(19) United States
(12) Patent Application Publication
(10) Pub. No.: US 2026/0182071 A1
(43) Pub. Date: Jun. 25, 2026

(54) IMAGE SENSOR PACKAGE

(71) Applicant: Samsung Electronics Co., Ltd., Suwon-si (KR)

(72) Inventor: Ik Jun CHOI, Suwon-si (KR)

(21) Appl. No.: 19/348,276

(22) Filed: Oct. 2, 2025

(30) Foreign Application Priority Data
Dec. 23, 2024 (KR) 10-2024-0194277

(51) Int. Cl. H10F 39/00

(52) U.S. Cl. CPC H10F 39/811; H10F 39/018; H10F 39/804; H10F 39/809

(57) ABSTRACT

An image sensing package includes a first substrate including a first surface and a second surface opposite to the first surface and comprising a sensor region including plurality of active pixels, a second substrate including a first surface and a second surface opposite to the first surface, and comprising a through-hole extending from the first surface of the second substrate to the second surface of the second substrate, a wiring layer disposed between the first surface of the first substrate and the second surface of the second substrate, a lower electrode layer comprising a through electrode portion and a rear wiring portion, wherein the through electrode portion is formed in the through-hole and is connected to the wiring layer, and the rear wiring portion covers a portion of the first surface of the second substrate, a connection terminal disposed on the first surface of the second substrate and electrically connected to the rear wiring portion, and a pad structure disposed between the rear wiring portion and the connection terminal to electrically connect the rear wiring portion and the connection terminal to each other, wherein the pad structure comprises a contact pad disposed on the rear wiring portion, and a conductive capping layer disposed between the contact pad and the connection terminal in the vertical direction, and in contact with both the contact pad and the connection terminal.

### CROSS-REFERENCE TO RELATED APPLICATION

This application claims priority from Korean Patent Application No. 10-2024-0194277 filed on Dec. 23, 2024, in the Korean Intellectual Property Office, and all the benefits accruing therefrom under 35 U.S.C. 119, the contents of which in its entirety are herein incorporated by reference.

### BACKGROUND

### Field

The present disclosure relates to an image sensor package.

### Description of Related Art

An image sensor for capturing an image and converting the image into an electrical signal is used not only for general consumer electronic devices such as a digital camera, a mobile phone camera, and a portable camcorder, but also for cameras mounted on automobiles, security devices, and robots. Therefore, an image sensor package in which an image sensor is implemented as a package has been developed and used as a core component.

### SUMMARY

A technical purpose to be achieved by the present disclosure is to provide an image sensor package capable of securing electrical connection reliability.

Another technical purpose to be achieved by the present disclosure is to provide a manufacturing process for forming an image sensor package having improved electrical connection reliability.

The technical purposes of the present disclosure are not limited to the technical purposes mentioned above, and other technical purposes not mentioned may be clearly understood by those skilled in the art from the following description.

According to an aspect of the disclosure, there is provided an image sensor package comprising: a first substrate including a first surface and a second surface opposite to the first surface and comprising a sensor region including plurality of active pixels; a second substrate including a first surface and a second surface opposite to the first surface, and comprising a through-hole extending from the first surface of the second substrate to the second surface of the second substrate; a wiring layer disposed between the first surface of the first substrate and the second surface of the second substrate; a lower electrode layer comprising a through electrode portion and a rear wiring portion, wherein the through electrode portion is formed in the through-hole and is connected to the wiring layer, and the rear wiring portion covers a portion of the first surface of the second substrate; a connection terminal disposed on the first surface of the second substrate and electrically connected to the rear wiring portion; and a pad structure disposed between the rear wiring portion and the connection terminal to electrically connect the rear wiring portion and the connection terminal to each other, wherein the pad structure comprises: a contact pad disposed on the rear wiring portion; and a conductive capping layer disposed between the contact pad and the connection terminal in a vertical direction, and in contact with both the contact pad and the connection terminal.

According to another aspect of the disclosure, there is provided an image sensor package comprising: a first substrate including a first surface and a second surface opposite to the first surface and including a sensor region having a plurality of active pixels; an upper wiring structure disposed on the first surface; a second substrate including a first surface and a second surface opposite to the second surface, wherein the second substrate comprises: a trench extending from the first surface of the second substrate into the second substrate; and a through-hole extending from a bottom surface of the trench to the second surface of the second substrate; a lower wiring structure disposed on the second surface of the second substrate and in contact with the upper wiring structure; a lower electrode layer comprising: a through electrode portion extending along an inner sidewall and a bottom surface of the through-hole and into the lower wiring structure, wherein the through electrode portion is electrically connected to a portion of the lower wiring structure; and a rear wiring portion covering a portion of the first surface of the second substrate; a plurality of connection terminals disposed on the first surface of the second substrate and electrically connected to the rear wiring portion; and a pad structure disposed between the rear wiring portion and the plurality of connection terminals to electrically connect the rear wiring portion and the plurality of connection terminals, wherein the pad structure comprises: a plurality of contact pads disposed on the rear wiring portion; and a plurality of conductive capping layers respectively disposed on the plurality of contact pads, wherein a portion of each of the plurality of conductive capping layers is spaced apart from each of the plurality of contact pads.

According to the other aspect of the disclosure, there is provided an image sensor package comprising: a first substrate having a first surface and a second surface opposite to the first surface and comprising a sensor region including plurality of active pixels; a glass plate disposed on the second surface of the first substrate; a dam structure disposed between the glass plate and the first substrate and including an outer side surface vertically aligned with a side surface of the glass plate; an upper wiring structure disposed on the first surface of the first substrate and including a stacked structure of a plurality of upper wiring patterns and a plurality of upper wiring vias; a second substrate having a first surface and a second surface opposite to the first surface, wherein the second substrate comprises: a trench extending from the first surface of the second substrate into the second substrate; and a through-hole extending from a bottom surface of the trench to the second surface of the second substrate; a lower wiring structure disposed on the second surface of the second substrate and in contact with the upper wiring structure, the lower wiring structure comprising a stacked structure of a plurality of lower wiring patterns and a plurality of lower wiring vias; a first passivation layer covering an inner sidewall of the trench, an inner sidewall of the through-hole, and the first surface of the second substrate; a lower electrode layer comprising: a through electrode portion disposed on the first passivation layer and covering the inner sidewall and a bottom surface of the through-hole and extending into the lower wiring structure to be electrically connected to some of the plurality of lower wiring patterns; and a rear wiring portion electrically connected to the through electrode portion and disposed on a portion of the first passivation layer covering the first surface of the second substrate; a second passivation layer covering a portion of the lower electrode layer and having a plurality of first openings defined therein to expose the lower electrode layer; a contact pad disposed in each of the first openings and electrically connected to the lower electrode layer; a third passivation layer covering the second passivation layer and having a plurality of second openings defined therein to expose a portion of the contact pad; a conductive capping layer partially disposed in each of the second openings and electrically connected to the contact pad; and a plurality of connection terminals disposed on the conductive capping layer and electrically connected to the rear wiring portion, the contact pad, and the conductive capping layer.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a cross-sectional view illustrating an image sensor package according to some embodiments of the present disclosure.

FIG. 2 is an enlarged view illustrating an area IB of FIG. 1.

FIG. 3 is an enlarged view illustrating an area IC of FIG. 1.

FIG. 4 is an enlarged view illustrating an area ID of FIG. 1.

FIGS. 5 to 16 are cross-sectional views illustrating a method of manufacturing an image sensor package according to example embodiments.

FIG. 17 is a block diagram illustrating a configuration of an image sensor package according to some embodiments of the present disclosure.

### DETAILED DESCRIPTIONS

Hereinafter, an image sensor package thereof according to some example embodiments will be described in detail with reference to the accompanying drawings.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

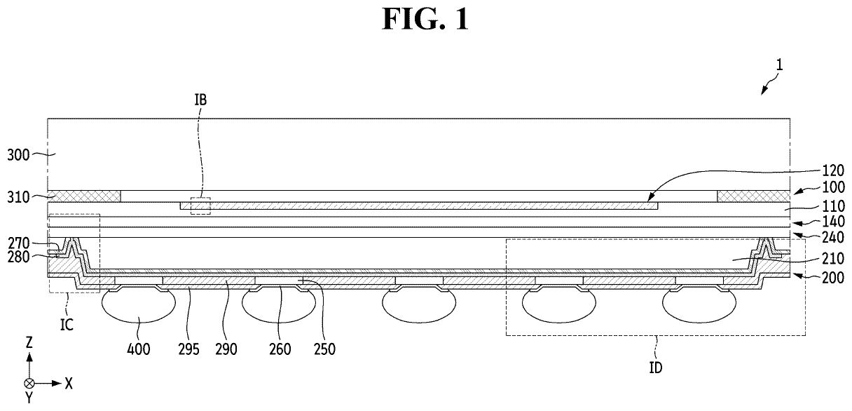

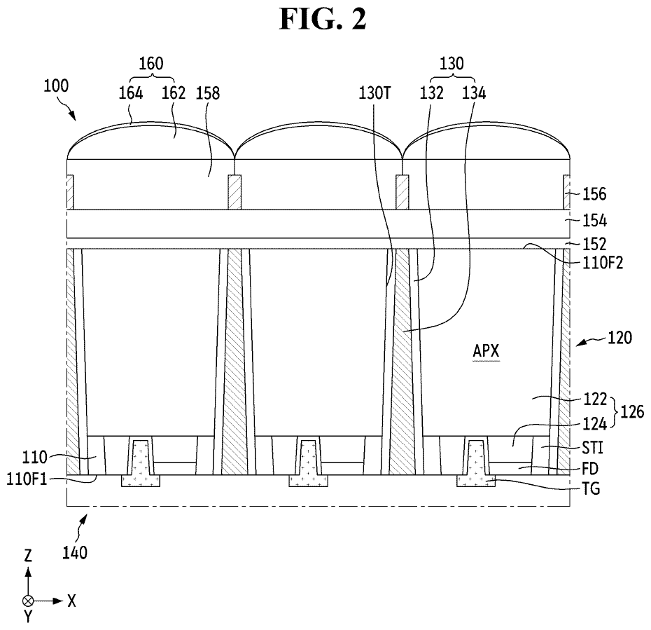

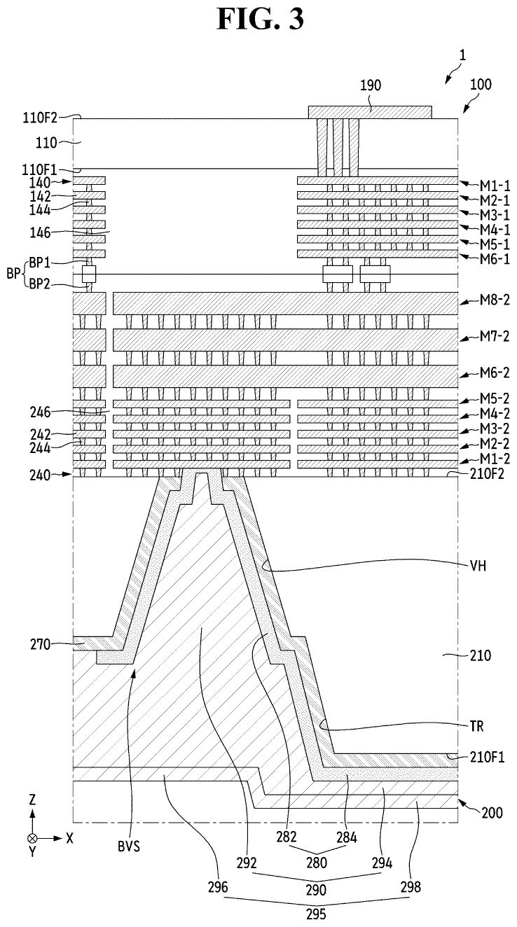

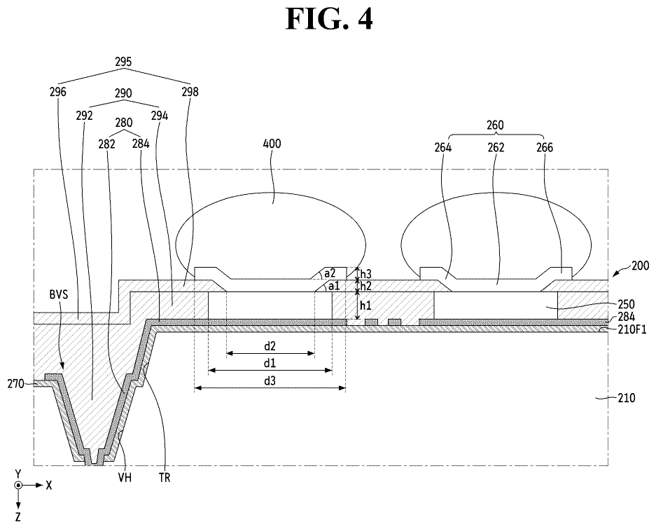

FIG. 1 is a cross-sectional view illustrating an image sensor package according to some embodiments of the present disclosure. FIG. 2 is an enlarged view illustrating an area IB of FIG. 1. FIG. 3 is an enlarged view illustrating an area IC of FIG. 1. FIG. 4 is an enlarged view illustrating an area ID of FIG. 1.

Referring to FIG. 1, an image sensor package 1 may include a first substrate unit 100, a second substrate unit 200, a dam structure 310, and a glass plate 300. In the image sensor package 1, the first substrate unit 100 may be stacked on the second substrate unit 200 in a vertical direction (Z direction), the dam structure 310 may be attached to the first substrate unit 100, and the glass plate 300 may be stacked on the dam structure 310 in the vertical direction (Z direction).

The first substrate unit 100 may include a first substrate 110, a sensor 120, and an upper wiring structure 140.

The first substrate 110 may include a crystalline semiconductor substrate and be an initial substrate (or base substrate) on which additional layers are formed to constitute the first unit substrate 100. For example, the first substrate 110 may include a Group IV semiconductor material, a Group III-V semiconductor material, or a Group II-VI semiconductor material. The Group IV semiconductor material may include, for example, silicon (Si), germanium (Ge), or silicon germanium (SiGe). The Group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The Group II-VI semiconductor material may include, for example, zinc telluride (ZnTe) or cadmium sulfide (CdS).

In some embodiments, the first substrate 110 may be embodied as a P-type silicon substrate. In some further embodiments, the first substrate 110 may include a P-type bulk substrate and a P-type or N-type epitaxial layer grown thereon. In some still further embodiments, the first substrate 110 may include a N-type bulk substrate and a P-type or N-type epitaxial layer grown on the N-type bulk substrate. In some further embodiments, the first substrate 110 may be embodied as an organic plastic substrate.

The sensor 120 may include, for example, a CIS (CMOS Image Sensor) or a CCD (Charge-Coupled Device). In some embodiments, a plurality of active pixels (APX in FIG. 2) may be arranged in a matrix form in the sensor 120.

The upper wiring structure 140 will be described in detail with reference to FIG. 3.

The second substrate unit 200 may include a second substrate 210 and a lower wiring structure 240. The second substrate unit 200 may be stacked on the first substrate unit 100 such that the lower wiring structure 240 is in contact with the upper wiring structure 140. The second substrate 210 may include a crystalline semiconductor substrate and be an initial substrate (or base substrate) on which additional layers are formed to constitute the second unit substrate 200. The upper wiring structure 140 and the lower wiring structure 240 may collectively be referred to as a wiring layer.

In some embodiments, the second substrate 210 may be made of the same or similar material as that of the first substrate 110.

The lower wiring structure 240 will be described in detail with reference to FIG. 3.

The second substrate unit 200 may include the second substrate 210, a lower electrode layer 280, a first passivation layer 270, a second passivation layer 290, a contact pad 250, a third passivation layer 295, and a conductive capping layer 260.

Specifically, the second substrate unit 200 may include the lower electrode layer 280 extending through the second substrate 210 so as to be connected to the lower wiring structure 240. For example, the lower electrode layer 280 may contact the lower wiring structure 240. The first passivation layer 270 may be interposed between the lower electrode layer 280 and the second substrate 210. The first passivation layer 270 may contact the lower electrode layer 280 and the second substrate 210. The second passivation layer 290 may be disposed on and in contact with the lower electrode layer 280. The third passivation layer 295 may be disposed on and in contact with the second passivation layer 290.

The lower electrode layer 280 may be interposed between and in contact with the first passivation layer 270 and the second passivation layer 290. The lower electrode layer 280 may extend through the first passivation layer 270 so as to be connected to the lower wiring structure 240.

The first passivation layer 270 may be made of, for example, oxide, nitride, oxynitride, or a combination thereof. In some embodiments, the first passivation layer 270 may have a stacked structure of a hafnium oxide film, a silicon nitride film, and a hafnium oxide film. For example, the first passivation layer 270 may have a thickness of about 100 mm to about 300 mm.

The lower electrode layer 280 may be made of, for example, a metal material such as titanium, titanium nitride, tantalum, tantalum nitride, titanium tungsten, tungsten, aluminum, cobalt, nickel, copper, or an alloy material including the same. In some embodiments, the lower electrode layer 280 may be formed in a CVD process or a ALD process. For example, the lower electrode layer 280 may have a thickness of about 2 μm to about 4 μm.

The second passivation layer 290 may be made of an insulating material such as silicon oxide or silicon nitride. In some embodiments, the second passivation layer 290 may include tetraethyl orthosilicate (TEOS) or plasma enhanced TEOS (PE-TEOS).

The contact pad 250 may be buried in the second passivation layer 290. The contact pad 250 may be located at the same vertical level as a vertical level of the second passivation layer 290. For example, a first surface of the contact pad 250 may be coplanar with a first surface of the second passivation layer 290, and a second surface of the contact pad 250 may be coplanar with a second surface of the second passivation layer 290. The contact pad 250 may be located on an area from which the second passivation layer 290 is partially removed, and may be physically and electrically connected to the lower electrode layer 280. The contact pad 250 may be made of a conductive material, for example, copper (Cu), aluminum (Al), silver (Ag), tin (Tin), gold (Au), or solder. However, the present disclosure is not limited thereto.

The third passivation layer 295 may cover a portion of the second passivation layer 290 and a portion of the contact pad 250. For example, the third passivation layer 295 may contact a portion of the second passivation layer 290 and a portion of the contact pad 250. The third passivation layer 295 may be made of, for example, an insulating material such as silicon oxide, silicon nitride, or the like. In some embodiments, the third passivation layer 295 may include tetraethyl orthosilicate (TEOS) or plasma enhanced TEOS (PE-TEOS). In some embodiments, the third passivation layer 295 may be made of the same material as that of the second passivation layer 290.

A portion of the conductive capping layer 260 may be buried in the third passivation layer 295. For example, a first portion of the conductive capping layer 260 may be located in an area in which the third passivation layer 295 is partially removed. The first portion of the conductive capping layer 260 may be located on and in contact with the contact pad 250. The conductive capping layer 260 may be electrically connected to the lower electrode layer 280 via the contact pad 250. A second portion of the conductive capping layer 260 may be located on and in contact with the third passivation layer 295. The conductive capping layer 260 may be made of a conductive material, for example, copper (Cu), aluminum (Al), silver (Ag), tin (Tin), gold (Au), or solder. However, the present disclosure is not limited thereto. the contact pad 250 and the conductive capping layer 260 may be collectively referred to as a pad structure.

A plurality of connection terminals 400 may be attached to a lower surface of the second substrate unit 200. For example, the plurality of connection terminals 400 may be disposed on a first surface (210F1 in FIG. 3) of the second substrate 210. The second passivation layer 290 may not cover portions of the lower electrode layer 280. The plurality of connection terminals 400 may be connected to the portions of the lower electrode layer 280, that are not covered by the second passivation layer 290, via the contact pad 250 and the conductive capping layer 260 on the lower electrode layer 280. Each of the plurality of connection terminals 400 may be electrically connected to the lower wiring structure 240 via the lower electrode layer 280, the contact pad 250, and the conductive capping layer 260.

The glass plate 300 may be disposed on the first substrate unit 100. For example, the glass plate 300 may be disposed on a second surface (110F2 in FIGS. 2 and 3) of the first substrate 110. The dam structure 310 may be interposed between the glass plate 300 and the first substrate 110. The glass plate 300 may be disposed to be spaced apart from the first substrate unit 100 by a predetermined distance in the vertical direction (Z direction). For example, the glass plate 300 may be disposed to be spaced apart from the sensor 120 in the vertical direction (Z direction). The glass plate 300 may be made of a transparent material capable of introducing light for forming an image into the sensor 120 therethrough.

In some embodiments, the glass plate 300 may include an IRCF (IR cut-off filter) and/or a blue glass (or a blue filter) for an infrared filter. In some further embodiments, the glass plate 300 may be replaced with a film filter made of a film material. However, the material of the glass plate 300 is not limited thereto, and may include a material configured to allow light for the image formation to be incident on the sensor 120 therethrough.

A horizontal area size of the glass plate 300 may be greater than a horizontal area size of the sensor 120. In some embodiments, the horizontal area size of the glass plate 300 may be substantially the same as the horizontal area size of the first substrate unit 100. In some embodiments, the horizontal area size of the first substrate unit 100 may be substantially the same as the horizontal area size of the second substrate unit 200. For example, the horizontal areas of the first substrate unit 100, the second substrate unit 200, and the glass plate 300 may be substantially the same as each other, and all of the first substrate unit 100, the second substrate unit 200, and the glass plate 300 may overlap each other in the vertical direction (Z direction). For example, side surfaces of the first substrate unit 100, the second substrate unit 200, and the glass plate 300 may vertically aligned with each other.

In some embodiments, the horizontal area size of the glass plate 300 may be substantially the same as a horizontal area size occupied with an inner space defined by an outer surface of the dam structure 310. For example, in an embodiment in which the horizontal area size of the glass plate 300 is substantially the same as a horizontal area size occupied with an inner space defined by an outer surface of the dam structure 310, a side surface of the first substrate unit 100, a side surface of the second substrate unit 200, and an outer side surface of the dam structure 310 may be aligned with each other in the vertical direction (Z direction). Additionally, in such an embodiment, the side surface of the glass plate 300 may be aligned with an inner side surface of the dam structure 310 in the vertical direction (Z direction). Further, in such an embodiment, the lower surface of the glass plate 300 may be substantially coplanar with an upper surface of the dam structure 310. Therefore, the glass plate 300 may be disposed on the first substrate unit 100, and the dam structure 310 may not be interposed between the glass plate 300 and the first substrate 110.

Referring to FIGS. 1 and 2, the first substrate unit 100 of the image sensor package 1 may include the first substrate 110, the sensor 120, and the upper wiring structure 140. The first substrate 110 may include a first surface 110F1 and a second surface 110F2 opposite to each other. In this regard, for convenience, a surface of the first substrate 110 on which a color filter layer 158 is disposed is referred to as the second surface 110F2, and a surface opposite to the second surface 110F2 is referred to as the first surface 110F1. However, the technical idea of the present disclosure is not limited thereto.

The sensor 120 may include the plurality of active pixels APX arranged in a matrix form and disposed in the first substrate 110. A plurality of photodiode regions 126 each including a photodiode 122 and a well 124 may be respectively disposed in the plurality of active pixels APX. A photodiode isolation pattern 130 may be disposed in the first substrate 110, and the plurality of active pixels APX may be defined by the photodiode isolation pattern 130. The photodiode isolation pattern 130 may be disposed between adjacent ones of the plurality of photodiode regions 126. The adjacent ones of the photodiode regions 126 may be physically and electrically isolated from each other via the photodiode isolation pattern 130. The photodiode isolation pattern 130 may be disposed between adjacent ones of the plurality of photodiode regions 126 arranged in a matrix form, and may have a grid or mesh shape in a plan view.

The photodiode isolation pattern 130 may be formed in a pixel trench 130T extending from the first surface 110F1 to the second surface 110F2 of the first substrate 110 through the first substrate 110. The photodiode isolation pattern 130 may include an insulating liner 132 conformally formed on a sidewall of the pixel trench 130T, and a buried conductive layer 134 disposed on the insulating liner 132 so as to fill an inside of the pixel trench 130T.

In some embodiments, the insulating liner 132 may include a metal oxide such as hafnium oxide, aluminum oxide, tantalum oxide, or the like. In some further embodiments, the insulating liner 132 may include an insulating material such as silicon oxide, silicon nitride, silicon oxynitride, or the like. The buried conductive layer 134 may include, for example, at least one of doped polysilicon, a metal, a metal silicide, a metal nitride, or a metal-containing film.

In some embodiments, the photodiode isolation pattern 130 may have a tapered shape extending from the same vertical level as that of the first surface 110a of the first substrate 110 to the same vertical level as that of the second surface 110F2 thereof. A horizontal width in a first horizontal direction (X direction) of the tapered shape is smaller as the tapered shape extends in a direction from the same vertical level as that of the first surface 110a of the first substrate 110 to the same vertical level as that of the second surface 110F2 thereof.

An element isolation film STI defining an active area (not shown) and a floating diffusion region FD may be formed on the first surface 110F1 of the first substrate 110. In some embodiments, gate electrodes constituting a plurality of transistors may be formed on the first surface 110F1 of the first substrate 110. For example, the plurality of transistors may include a transfer transistor configured to transfer charges generated in the photodiode region 126 to the floating diffusion region FD, a reset transistor configured to periodically reset charges stored in the floating diffusion region FD, a drive transistor configured to serve as a source follower buffer amplifier and buffer a signal based on the charges charged in the floating diffusion area, and a select transistor configured to perform switching and addressing for selecting the active pixel area APR. However, the plurality of transistors are not limited thereto.

FIG. 2 illustrates an example of a transfer gate TG constituting the transfer transistor among the gate electrodes constituting the plurality of transistors. Although an example in which the transfer gate TG constituting the transfer transistor is formed in a recess gate form extending from the first surface 110F1 of the first substrate 110 into the first substrate 110 is illustrated, a form of the transfer gate TG is not limited thereto.

In some further embodiments, a reset gate constituting the reset transistor, a source follower gate constituting the drive transistor, and a select gate constituting the select transistor among the plurality of transistors may be formed on the second substrate 210 so as to be included in the second substrate unit 200.

The upper wiring structure 140 may be disposed on the first surface 110F1 of the first substrate 110. The upper wiring structure 140 may be electrically connected to the gate electrodes GE or the active area AR of the first substrate 110. For example, the upper wiring structure 140 may include a conductive material such as tungsten, aluminum, copper, tungsten silicide, titanium silicide, tungsten nitride, titanium nitride, doped polysilicon, or the like, and an insulating material such as silicon oxide, silicon nitride, silicon oxynitride, or the like.

A cover insulating layer 152 may be disposed on the second surface 110F2 of the first substrate 110. In some embodiments, the cover insulating layer 152 may cover an entirety of a portion of the second surface 110F2 of the first substrate 110 corresponding to the sensor 120. The cover insulating layer 152 may be in contact with an upper surface of the photodiode isolation pattern 130 positioned at the same vertical level as a vertical level of the second surface 110F2 of the first substrate 110. In some embodiments, the cover insulating layer 152 may include a metal oxide such as aluminum oxide, tantalum oxide, or the like.

A front passivation layer 154 may cover the cover insulating layer 152 disposed on the second surface 110F2 of the first substrate 110. The front passivation layer 154 may be made of, for example, oxide, nitride, oxynitride, or a combination thereof. In some embodiments, the front passivation layer 154 may have a stacked structure of a hafnium oxide film, a silicon nitride film, and a hafnium oxide film.

A guide pattern (i.e., grid) 156 may be formed on the front passivation layer 154. In a plan view, the guide pattern 156 may have a grid shape or a mesh shape. The guide pattern 156 may prevent light obliquely incident to one photodiode region 126 from entering another photodiode region 126 adjacent thereto. The guide pattern 156 may include, for example, at least one metal material of tungsten, aluminum, titanium, ruthenium, cobalt, nickel, copper, gold, silver, or platinum.

The color filter layer 158 overlapping the photodiode region 126 and the microlens 160 disposed on the color filter layer 158 may be formed on the front passivation layer 154 on which the guide pattern 156 has been formed. The color filter layer 158 may transmit light incident thereto through the microlens 160 therethrough to allow only a light portion having a required wavelength to be incident to the photodiode region 126.

The color filter layer 158 may include, for example, a red (R) filter, a blue (B) filter, and a green (G) filter. Alternatively, the color filter layer 158 may include a cyan (C) filter, a yellow (Y) filter, and a magenta (M) filter. The color filter layer 158 of one of the R filter, the B filter, and the G filter, or the color filter layer 158 of one of the C filter, the Y filter, and the M filter may be formed on each of the active pixels APX, so that each active pixel APX may detect a separated component of the incident light to recognize one color.

The microlens 160 may condense light incident on the image sensor package 1 on the active pixel APX. In some embodiments, the microlens 160 may include an organic material layer 162 and an inorganic material layer 164 conformally covering a surface of the organic material layer 162. For example, the organic material layer 162 may be made of a TMR-based resin (Tokyo Ohka Kogyo, Co. product) or a MFR-based resin (Japan Synthetic Rubber Corporation product).

As discussed above, referring to FIGS. 1 and 3, the first substrate unit 100 of the image sensor package 1 may include the first substrate 110 and the upper wiring structure 140. The first substrate 110 may include the first surface 110F1 and the second surface 110F2 opposite to each other. The upper wiring structure 140 may be disposed on the first surface 110F1 of the first substrate 110. As illustrated in FIG. 3, the upper wiring structure 140 may include a stacked structure of a plurality of upper wiring patterns 142 and a plurality of upper wiring vias 144, and an upper interlayer insulating film 146 surrounding the plurality of upper wiring patterns 142 and the plurality of upper wiring vias 144.

In some embodiments, the upper wiring structure 140 may be formed using a damascene process. In some embodiments, at least one of the plurality of upper wiring patterns 142 and at least one of the plurality of upper wiring vias 144 may be integrally formed with each other. In some embodiments, each of the plurality of upper wiring patterns 142 and the plurality of upper wiring vias 144 may have a tapered shape in which a horizontal width thereof is smaller as each of the plurality of upper wiring patterns 142 and the plurality of upper wiring vias 144 extends from a lower side to an upper side. For example, the horizontal width of each of the plurality of upper wiring patterns 142 and the plurality of upper wiring vias 144 may increase as each of the plurality of upper wiring patterns 142 and the plurality of upper wiring vias 144 extends away from the first substrate 110.

The plurality of upper wiring patterns 142 may include a plurality of upper patterns positioned at different vertical levels. For example, the plurality of upper wiring patterns 142 may include a first upper pattern M1-1, a second upper pattern M2-1, a third upper pattern M3-1, a fourth upper pattern M4-1, a fifth upper pattern M5-1, and a sixth upper pattern M6-1, which are located at different vertical levels.

The plurality of upper wiring vias 144 may be connected to at least one of the first upper pattern M1-1, the second upper pattern M2-1, the third upper pattern M3-1, the fourth upper pattern M4-1, the fifth upper pattern M5-1, and the sixth upper pattern M6-1.

The upper interlayer insulating film 146 may be disposed on the first surface 110F1 of the first substrate 110 so as to surround the plurality of upper wiring patterns 142 and the plurality of upper wiring vias 144. The upper interlayer insulating film 146 may include an insulating material such as silicon oxide, silicon nitride, silicon oxynitride, or the like.

In some embodiments, the upper wiring structure 140 may include a plurality of first bonding pads BP1. The plurality of first bonding pads BP1 may be electrically connected to the plurality of upper wiring patterns 142 and the plurality of upper wiring vias 144. For example, each of the plurality of first bonding pads BP1 may be connected to at least one of the plurality of upper wiring vias 144. The plurality of first bonding pads BP1 may be disposed on a lower surface of the upper wiring structure 140 facing the lower wiring structure 240. For example, a lower surface of each of the plurality of first bonding pads BP1 and a lower surface of the upper interlayer insulating film 146 facing the lower wiring structure 240 may be coplanar with each other.

As discussed above, the second substrate unit 200 of the image sensor package 1 may include the second substrate 210 and the lower wiring structure 240. The second substrate 110 may include a first surface 210F1 and a second surface 210F2 opposite to each other. In this regard, for convenience, a surface of the second substrate 210 on which the lower wiring structure 240 is disposed is referred to as the first surface 210F1 of the second substrate 210, and a surface opposite to the first surface 210F1 of the second substrate 210 is referred to as the second surface 210F2 of the second substrate 210. However, the technical idea of the present disclosure is not limited thereto.

The lower wiring structure 240 may be interposed between the upper wiring structure 140 and the second substrate 210 so as to be in contact with the upper wiring structure 140 and the second substrate 210.

The lower wiring structure 240 may include a stacked structure of a plurality of lower wiring patterns 242 and a plurality of lower wiring vias 244, and a lower interlayer insulating film 246 surrounding the plurality of lower wiring patterns 242 and the plurality of lower wiring vias 244

In some embodiments, the lower wiring structure 240 may be formed using a damascene process. In some embodiments, at least one of the plurality of lower wiring patterns 242 and at least one of the plurality of lower wiring vias 244 may be integrally formed with each other. In some embodiments, each of the plurality of lower wiring patterns 242 and the plurality of lower wiring vias 244 may have a tapered shape in which a horizontal width thereof is smaller as each of the plurality of lower wiring patterns 242 and the plurality of lower wiring vias 244 extends from an upper side to a lower side. For example, each of the plurality of lower wiring patterns 242 and the plurality of lower wiring vias 244 may have the horizontal width that increases as each of the plurality of lower wiring patterns 242 and the plurality of lower wiring vias 244 extends away from the second substrate 210.

The plurality of lower wiring patterns 242 may include a plurality of lower patterns positioned at different vertical levels. For example, the plurality of lower wiring patterns 242 may include a first lower pattern M1-2, a second lower pattern M2-2, a third lower pattern M3-2, a fourth lower pattern M4-2, a fifth lower pattern M5-2, a sixth lower pattern M6-2, a seventh lower pattern M7-2, and an eighth lower pattern M8-2 which are located at different vertical levels.

As used herein, each of the first lower pattern M1-2, the second lower pattern M2-2, the third lower pattern M3-2, the fourth lower pattern M4-2, the fifth lower pattern M5-2, the sixth lower pattern M6-2, the seventh lower pattern M7-2, and the eighth lower pattern M8-2 may be referred to as the first wiring pattern M1-2, the second wiring pattern M2-2, the third wiring pattern M3-2, the fourth wiring pattern M4-2, the fifth wiring pattern M5-2, the sixth wiring pattern M6-2, the seventh wiring pattern M7-2, and the eighth wiring pattern 8-2, respectively.

The plurality of lower wiring vias 244 may be connected to at least one of the second lower pattern M1-2, the second lower pattern M2-2, the third lower pattern M3-2, the fourth lower pattern M4-2, the fifth lower pattern M5-2, the sixth lower pattern M6-2, the seventh lower pattern M7-2, and the eighth lower pattern M8-2.

The lower interlayer insulating film 246 may be disposed on the first surface 210F1 of the second substrate 210 so as to surround the plurality of lower wiring patterns 242 and the plurality of lower wiring vias 244. The lower interlayer insulating film 246 may include an insulating material such as silicon oxide, silicon nitride, silicon oxynitride, or the like.

In some embodiments, the lower wiring structure 240 may include a plurality of second bonding pads BP2. The plurality of second bonding pads BP2 may be electrically connected to the plurality of lower wiring patterns 242 and the plurality of lower wiring vias 244. For example, each of the plurality of second bonding pads BP2 may be connected to at least one of the plurality of lower wiring vias 244. The plurality of second bonding pads BP2 may be disposed on an upper surface of the lower wiring structure 240 facing the upper wiring structure 140. For example, an upper surface of each of the plurality of second bonding pads BP2 and an upper surface of the lower interlayer insulating film 246 facing the upper wiring structure 140 may be coplanar with each other.

The first bonding pad BP1 and the second bonding pad BP2 corresponding to each other may constitute a bonding pad BP (e.g., a first bonding pad BP1 in contact with a corresponding second bonding pad BP2 may constitute a bonding pad BP). A plurality of bonding pads BP may be disposed at an interface between the first substrate unit 100 and the second substrate unit 200, that is, an interface between the upper interlayer insulating film 146 of the upper wiring structure 140 and the lower interlayer insulating film 246 of the lower wiring structure 240. The first bonding pad BP1 and the second bonding pad BP2 corresponding to each other to constitute the bonding pad BP may be disposed to vertically overlap each other and may be attached to each other. For example, a bonding interface as an interface between the first bonding pad BP1 and the second bonding pad BP2 may be coplanar with an interface between the upper interlayer insulating film 146 of the upper wiring structure 140 and the lower interlayer insulating film 246 of the lower wiring structure 240. The first bonding pad BP1 and the second bonding pad BP2 corresponding to each other may expand under heat so as to be in contact with each other, and then may be diffusion-bonded to each other via diffusion of metal atoms included therein to be integral with each other, thereby forming the bonding pad BP. For example, the first substrate unit 100 and the second substrate unit 200 may be stacked in a metal-oxide hybrid bonding manner.

As discussed above, referring to FIGS. 1, 3, and 4, the second substrate unit 200 may include the second substrate 210, the first passivation layer 270, the lower electrode layer 280, the second passivation layer 290, the contact pad 250, the third passivation layer 295, and the conductive capping layer 260.

Specifically, the second substrate unit 200 may include the lower electrode layer 280 extending through the second substrate 210 so as to be connected to the lower wiring structure 240, the first passivation layer 270 interposed between the lower electrode layer 280 and the second substrate 210, the second passivation layer 290 covering the lower electrode layer 280, the contact pad 250 embedded in the second passivation layer 290, the third passivation layer 295 covering the second passivation layer 290, and the conductive capping layer 260 on the contact pad 250.

The second substrate 210 may have a trench TR extending inwardly from the first surface 210F1 of the second substrate 210, and a through-hole VH extending from a bottom surface of the trench TR to the second surface 210F2 of the second substrate 210. The trench TR and the through-hole VH may communicate with each other.

Although FIGS. 3 and 4 show that the second substrate 210 has one through-hole VH, this is for convenience of illustration, and the technical idea of the present disclosure is not limited thereto. For example, the second substrate 210 may have a plurality of through-holes VH extending from the bottom surface of the trench TR to the second surface 210F2 of the second substrate 210. The through-hole VH may further extend from the second surface 210F2 of the second substrate 210 into the lower wiring structure 240. For example, the through-hole VH may be formed by removing a portion of the second substrate 210 and a portion of the lower interlayer insulating film 246. Some of the plurality of lower wiring patterns 242 may be exposed through the through-hole VH. For example, the first lower pattern M1-2 and the second lower pattern M2-2 may be exposed through the through-hole VH. The first lower pattern M1-2 and the second lower pattern M2-2 may function as an etch stop film in a process of forming the through-hole VH.

The first passivation layer 270 may cover an inner sidewall of the trench TR, an inner sidewall of the through-hole VH, and the first surface 210F1 of the second substrate 210. In some embodiments, the first passivation layer 270 may cover a portion of the bottom surface of the trench TR.

The lower electrode layer 280 may cover the first passivation layer 270. The lower electrode layer 280 may extend through the first passivation layer 270 so as to be connected to the lower wiring structure 240. For example, the lower electrode layer 280 may be connected to some of the plurality of lower wiring patterns 242. For example, the lower electrode layer 280 may be in contact with and electrically connected to the first lower pattern M1-2 and the second lower pattern M2-2.

The lower electrode layer 280 may include a through electrode portion 282 and a rear wiring portion 284. The through electrode portion 282 and the rear wiring portion 284 may be electrically connected to each other. The through electrode portion 282 may be a portion of the lower electrode layer 280 covering an inner sidewall and a bottom surface of the through-hole VH, and connected to some of the plurality of lower wiring patterns 242. For example, the through electrode portion 282 may be in contact with and electrically connected to the first lower pattern M1-2 and the second lower pattern M2-2.

The rear wiring portion 284 may be a portion of the lower electrode layer 280 disposed on a portion of the first passivation layer 270 covering the first surface 210F1 of the second substrate 210. For example, the rear wiring portion 284 may be a line pattern.

In some embodiments, the rear wiring portion 284 may extend from a portion of the first passivation layer 270 covering the first surface 210F1 of the second substrate 210 to a portion of the first passivation layer 270 covering a side surface of the trench TR, and may be connected to the through electrode portion 282.

The rear wiring portion 284 may be electrically connected to the connection terminal 400 illustrated in FIG. 1 via the contact pad 250 and the conductive capping layer 260.

The second passivation layer 290 may cover a portion of the lower electrode layer 280. The lower electrode layer 280 may be interposed between the first passivation layer 270 and the second passivation layer 290.

The second passivation layer 290 may include a first buried portion 292 and a first rear passivation portion 294. The first buried portion 292 may be a portion of the second passivation layer 290 that covers the through electrode portion 282 and fills the through-hole VH. The first rear passivation portion 294 may be a portion of the second passivation layer 290 covering the rear wiring portion 284. For example, the first rear passivation portion 294 may fill at least a portion of the trench TR and may cover the first surface 210F1 of the second substrate 210.

The contact pad 250 may be located at the same vertical level as a vertical level of the second passivation layer 290. The contact pad 250 may be buried in the second passivation layer 290.

In some embodiments, the contact pad 250 may have a cylindrical shape. In some embodiments, the contact pad 250 may have a polygonal pillar shape. A width in the horizontal direction of a cross-section of the contact pad 250 illustrated in FIG. 4 is referred to as a first width d1. A dimension in the vertical direction of the cross-section of the contact pad 250 illustrated in FIG. 4 is referred to as a first height h1. The first width d1 and the first height h1 may vary across different contact pads 250.

In some embodiments, the first width d1 may be smaller than a width of the cross-section of the connection terminal 400. Although it is illustrated only that the first width d1 is smaller than the width of the cross-section of the connection terminal 400, the present disclosure is not limited thereto. In some embodiments, the first width d1 may be greater than the width of the cross-section of the connection terminal 400.

In some embodiments, the first height h1 may be equal to a height of the second passivation layer 290. Although it is illustrated only that the first height h1 is equal to the height of the second passivation layer 290, the present disclosure is not limited thereto. In some embodiments, the first height h1 may be greater or smaller than the height of the second passivation layer 290.

In some embodiments, when each of the first width d1 and the first height h1 of the contact pad 250 increases, a volume of the contact pad 250 may increase, and thus, the coefficient of thermal expansion (CTE) of the contact pad 250 may increase. When the coefficient of thermal expansion of the contact pad 250 increases, a difference between the CTEs of the contact pad 250 and an external connection terminal (not shown) may decrease. Accordingly, the stability of the connection terminal 400 electrically connected to the contact pad 250 may increase. In addition, electrical connection reliability of the connection terminal 400 may increase.

The third passivation layer 295 may cover a portion of the second passivation layer 290. The third passivation layer 295 may be disposed on the second passivation layer 290. The third passivation layer 295 may include a second buried portion 296 and a second rear passivation portion 298. The second buried portion 296 may be a portion of the third passivation layer 295 that covers the through electrode portion 282 and the first buried portion 292 and fills the through-hole VH. The second rear passivation portion 298 may be a portion of the third passivation layer 295 covering the rear wiring portion 284 and the first rear passivation portion 294. For example, the second rear passivation portion 298 may fill at least a portion of the trench TR and may cover the first surface 210F1 of the second substrate 210.

A portion of the conductive capping layer 260 may be buried in the third passivation layer 295.

The conductive capping layer 260 includes a base portion 262 in contact with the contact pad 250, a peripheral portion 266 disposed on the third passivation layer 295 so as to be exposed, and a connection portion 264 connecting the base portion 262 and the peripheral portion 266. The base portion 262 and the peripheral portion 266 being disposed parallel to the an upper surface of the contact pad 250. The base portion 262 disposed at a first vertical level and the peripheral portion 266 disposed at a second vertical level different from the first vertical level. The base portion 262 may be referred to as the first portion of the conductive capping layer 260. The peripheral portion 266 and the connection portion 264 may be collectively referred to as the second portion of the conductive capping layer 260. In some embodiments, the conductive capping layer 260 may have a cylindrical shape with a concave center. In some embodiments, the conductive capping layer 260 may have a polygonal pillar shape having a concave center. The first portion of the conductive capping layer 260 may be located on and in contact with the contact pad 250. The second portion of the conductive capping layer 260 may be located on and in contact with the third passivation layer 295. The third passivation layer 295 may disposed directly between the second portion of the conductive capping layer 260 and the contact pad 250 in the vertical direction (Z direction) and may contact both the second portion of the conductive capping layer 260 and the contact pad 250.

Referring to FIG. 4, a width in the horizontal direction of the cross-section of the base portion 262 is referred to as a second width d2. The width in the horizontal direction of the cross section of the peripheral portion 266 is referred to as a third width d3. For example, the width in the horizontal direction of the cross section of the conductive capping layer 260 is referred to as a third width d3. A height in the vertical direction of the cross-section of the base portion 262 is referred to as a second height h2. The height in the vertical direction of the cross section of the peripheral portion 266 is referred to as a third height h3. An angle defined between a lower surface of the base portion 262 and the connection portion 264 is referred to as a first angle a1. An angle defined between an upper surface of the base portion 262 and the connection portion 264 is referred to as a second angle a2. The first angle a1 and the second angle a2 may be acute angles. The second width d2, the third width d3, the second height h2, the third height h3, the first angle a1, and the second angle a2 may vary across different conductive capping layers 260. The present disclosure is not limited to what is shown.

In some embodiments, the second width d2 may be smaller than the width of the cross-section of the connection terminal 400. Although not illustrated, in some embodiments, the third width d3 may be greater than the width of the cross-section of the connection terminal 400. Accordingly, a contact area between the conductive capping layer 260 and the connection terminal 400 may be increased. In addition, electrical connection reliability between the conductive capping layer 260 and the connection terminal 400 may be improved.

In some embodiments, the second height h2 may be equal to the height of the third passivation layer 295. The third height h3 may be equal to or different from the second height h2. Although it is illustrated only that the second height h2 is equal to the height of the third passivation layer 295, the present disclosure is not limited thereto. In some embodiments, the first height h1 may be greater or smaller than the height of the second passivation layer 290.

In some embodiments, the first angle a1 and the second angle a2 may be equal to each other. The first angle a1 and the second angle a2 may be adjusted according to the shape of the connection terminal 400, and may be different from each other. Accordingly, a contact area between the conductive capping layer 260 and the connection terminal 400 may be increased. In addition, electrical connection reliability between the conductive capping layer 260 and the connection terminal 400 may be improved.

In some embodiments, when the second width d2, the third width d3, the second height h2, and the third height h3 of the conductive capping layer 260 increase, the volume of the image sensor package 1 may increase. As the volume occupied by the conductive capping layer 260 in the image sensor package 1 increases, the Coefficient of thermal expansion (CTE) of the image sensor package 1 may increase. If the coefficient of thermal expansion of the image sensor package 1 increases, a difference between the CTEs of the image sensor package 1 and the external connection terminal (not shown) may decrease. Accordingly, the stability of the connection terminal 400 electrically connected to the conductive capping layer 260 in the image sensor package 1 may increase. In addition, electrical connection reliability of the connection terminal 400 may increase.

A combination of the through electrode portion 282, the first buried portion 292, and the second buried portion 296 may be referred to as a through electrode structure BVS. The through electrode structure BVS may be referred to as a back via stack.

Referring to FIGS. 1 to 4, the image sensor package 1 includes the through electrode structure BVS including the through electrode portion 282 covering an inner sidewall and a bottom surface of the through-hole VH. In the process of forming the through-hole VH, the first lower pattern M1-2 and the second lower pattern M2-2 may function as the etch stop film, and the through electrode portion 282 may be connected to the first lower pattern M1-2 and the second lower pattern M2-2.

Therefore, in the image sensor package 1 according to the present disclosure, a contact area between the through electrode portion 282 and the stack structure of the plurality of lower wiring patterns 242 and the plurality of lower wiring vias 244 included in the lower wiring structure 240 may increase, thereby reducing contact resistance. In addition, since the first lower pattern M1-2 and the second lower pattern M2-2 function as the etch stop film in the process of forming the through-hole VH, the through-hole VH may be formed by performing an etching process under a high etch selectivity, thereby improving the reliability of the manufacturing process for forming the image sensor package 1.

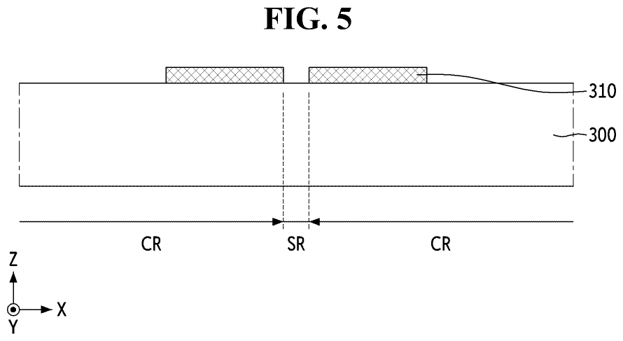

FIGS. 5 to 16 are cross-sectional views illustrating a method of manufacturing an image sensor package according to example embodiments. FIGS. 5 to 16 show a method for manufacturing the image sensor package 1 shown in FIGS. 1 to 4, and the image sensor package 1 shown in FIGS. 1 to 4 is obtained by turning the resulting structure of FIGS. 5 to 16 upside down.

Referring to FIG. 5, the dam structure 310 is attached onto the glass plate 300. The glass plate 300 includes a plurality of chip areas CR and a scribe lane area SR interposed between adjacent ones of the plurality of chip areas CR. Each of the plurality of chip areas CR of the glass plate 300 corresponds to a portion of the glass plate 300 included in the image sensor package 1 as shown in FIG. 1. The dam structure 310 may be attached to a portion of each of the plurality of chip areas CR adjacent to the scribe lane area SR of the glass plate 300. In some embodiments, the dam structure 310 may be attached to the glass plate 300 so as to extend along an edge of each of the plurality of chip areas CR. For example, the dam structure 310 may have a rectangular ring shape in a plan view.

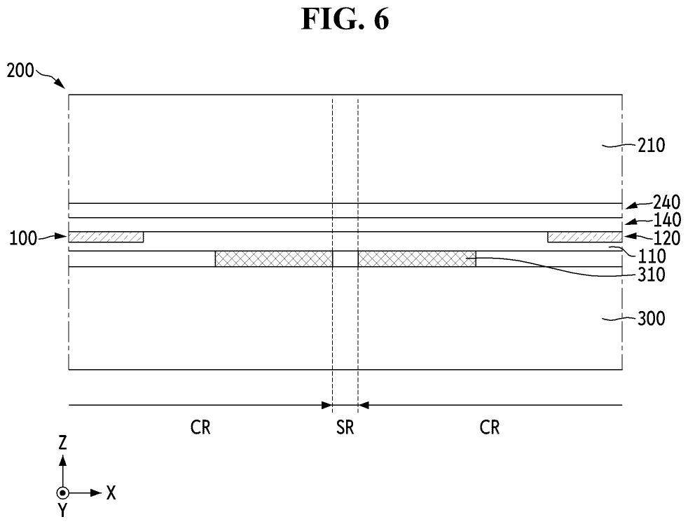

Referring to FIG. 6, the first substrate unit 100 in which the second substrate unit 200 is stacked is attached to the glass plate 300 to which the dam structure 310 is attached. The first substrate unit 100 and the second substrate unit 200 may be stacked in a metal-oxide hybrid bonding manner.

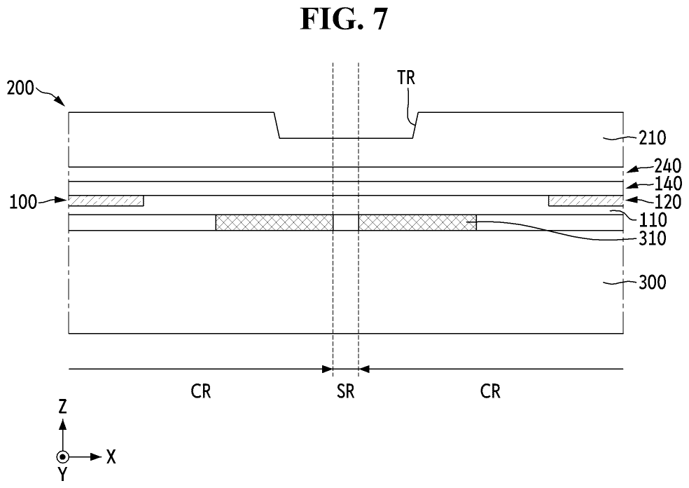

Referring to FIG. 7, a portion of the second substrate 210 is removed to form the trench TR. The trench TR may be formed by removing an upper portion of the second substrate 210 in an area corresponding to the scribe lane area SR and a portion of each of the plurality of chip areas CR that is in contact with the scribe lane area SR.

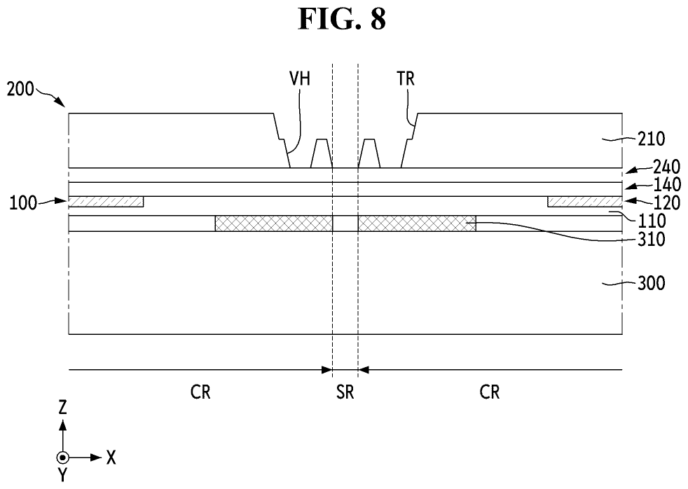

Referring to FIG. 8, a plurality of through-holes VH are formed by removing a portion of the second substrate 210 from the bottom surface of the trench TR. The trench TR and the plurality of through-holes VH may extend through the second substrate 210. Each of the plurality of through-holes VH may further extend into the lower wiring structure 240 as shown in FIG. 3.

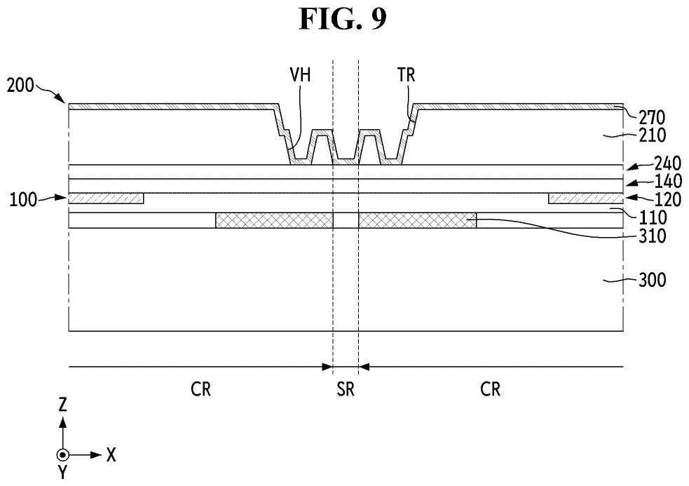

Referring to FIG. 9, the first passivation layer 270 is formed to cover the upper surface of the second substrate 210, the inner surface of the trench TR, the inner surfaces of the plurality of through-holes VH, and a portion of the upper surface of the lower wiring structure 240 exposed through the plurality of through-holes VH. The first passivation layer 270 may be formed to conformally cover the upper surface of the second substrate 210, the inner surface of the trench TR, the inner surfaces of the plurality of through-holes VH, and the portion of the upper surface of the lower wiring structure 240 exposed through the plurality of through-holes VH.

The first passivation layer 270 may be made of, for example, oxide, nitride, oxynitride, or a combination thereof. In some embodiments, the first passivation layer 270 may be formed to have a stacked structure of a hafnium oxide film, a silicon nitride film, and a hafnium oxide film. For example, the first passivation layer 270 may be formed to have a thickness of about 100 mm to about 300 mm.

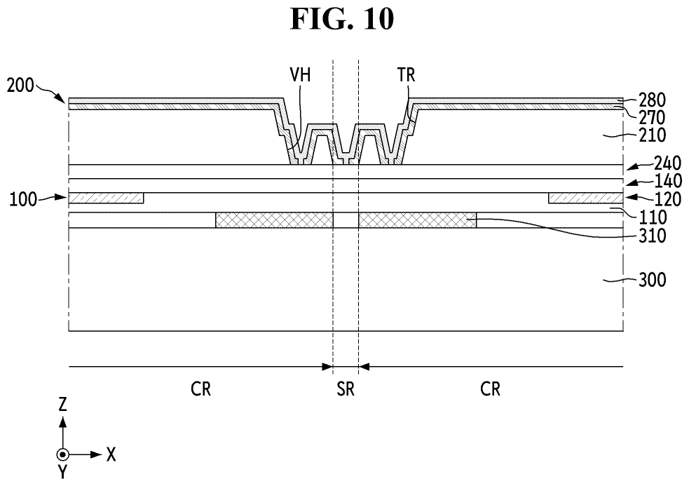

Referring to FIG. 10, after removing at least a portion of the first passivation layer 270 covering the portion of the upper surface of the lower wiring structure 240 exposed through the plurality of through-holes VH such that the lower wiring structure 240 is exposed, the lower electrode layer 280 covering the first passivation layer 270 and contacting a portion of the upper surface of the lower wiring structure 240 exposed through the plurality of through-holes VH is formed.

The lower electrode layer 280 may be made of, for example, a metal material such as titanium, titanium nitride, tantalum, tantalum nitride, titanium tungsten, tungsten, aluminum, cobalt, nickel, copper, or an alloy material including the same. In some embodiments, the lower electrode layer 280 may be formed in a CVD process or a ALD process. For example, the lower electrode layer 280 may be formed to have a thickness of about 2 μm to about 4 μm.

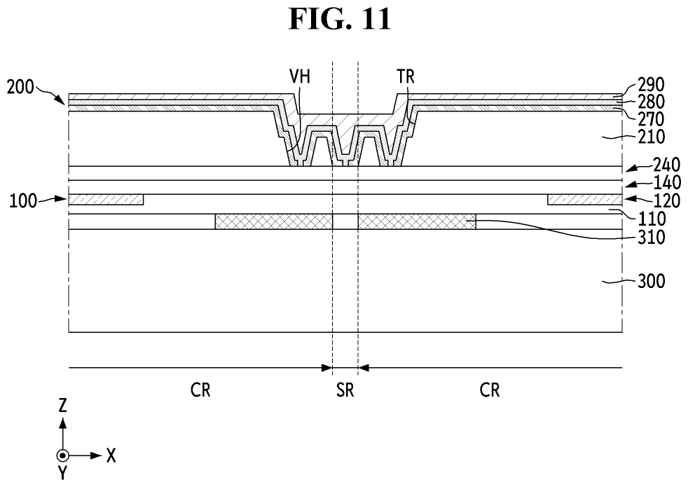

Referring to FIG. 11, the second passivation layer 290 covering the lower electrode layer 280 is formed. The second passivation layer 290 may be made of, for example, an insulating material such as silicon oxide, silicon nitride, or the like. In some embodiments, the second passivation layer 290 may be formed to include tetraethyl orthosilicate (TEOS) or plasma enhanced-TEOS (PE-TEOS).

The second passivation layer 290 may be formed to cover the lower electrode layer 280, to fill the through-hole VH, and to fill at least a portion of the trench TR.

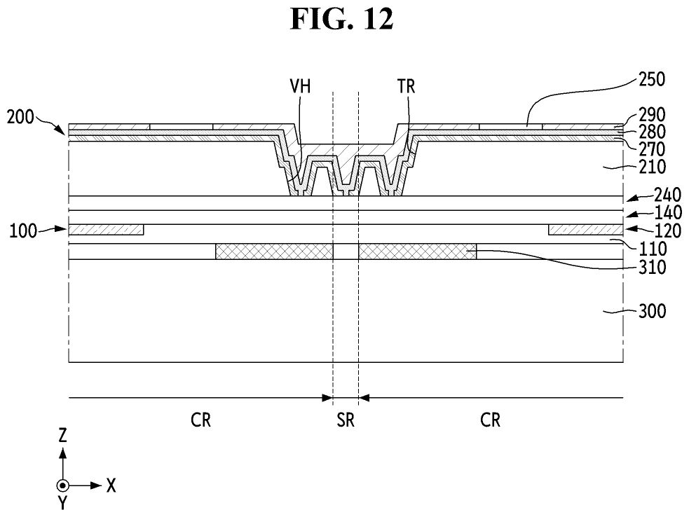

Referring to FIG. 12, a portion of the second passivation layer 290 is removed to form the contact pad 250.

For example, an area in which the second passivation layer 290 is removed may be an area in which the second passivation layer 290 overlaps the lower electrode layer 280 in the vertical direction (Z direction). In some embodiments, a portion of the second passivation layer 290 may be removed to expose a portion of the lower electrode layer 280.

In some embodiments, a photomask may be used to form the contact pad 250. A photomask on which a pattern is drawn may be disposed on the upper surface of the second passivation layer 290. The photomask may be designed to have various patterns in order to adjust the shape and width of the plurality of contact pads 250. In some embodiments, a size of an area from which the second passivation layer 290 is removed may be equal to a size of the contact pad 250.

Thereafter, the contact pad 250 and the second passivation layer 290 may be planarized in a planarization process. In the planarization process, an upper surface of the contact pad 250 and an upper surface of the second passivation layer 290 may be coplanar with each other. The planarization process may be performed, for example, using a chemical mechanical polishing (CMP) process.

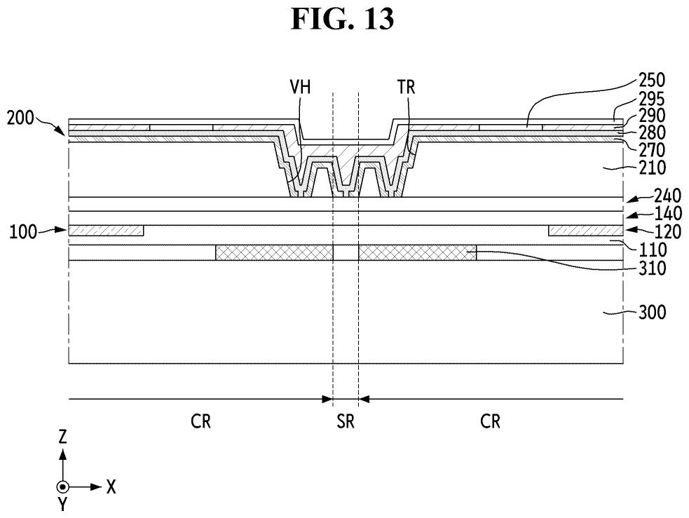

Referring to FIG. 13, the third passivation layer 295 covering the upper surface of the second passivation layer 290 and the upper surface of the contact pad 250 is formed. The third passivation layer 295 may be formed to conformally cover the second passivation layer 290 and the contact pad 250. The third passivation layer 295 may be formed to fill the through-hole VH and at least a portion of the trench TR.

In some embodiments, the third passivation layer 295 may be made of the same material as that of the second passivation layer 290. The third passivation layer 295 may be made of, for example, an insulating material such as silicon oxide, silicon nitride, or the like. In some embodiments, the third passivation layer 295 may be formed using a photosensitive resin such as photo-imageable dielectric (PID), photo solder resist, or the like.

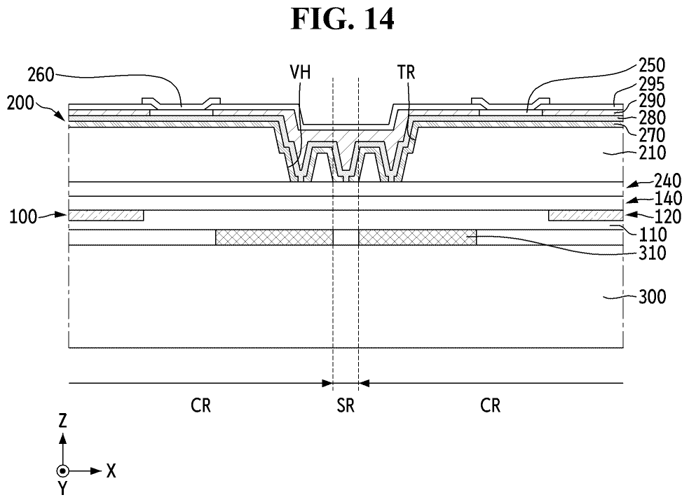

Referring to FIG. 14, the conductive capping layer 260 is formed by removing a portion of the third passivation layer 295.

For example, an area in which the third passivation layer 295 is removed may be an area in which the third passivation layer 295 overlaps the lower electrode layer 280 and the contact pad 250 in the vertical direction (Z direction). In some embodiments, a portion of the third passivation layer 295 may be removed to expose a portion of the contact pad 250.

In some embodiments, a photomask may be used to form the conductive capping layer 260. The photomask on which a pattern is drawn may be disposed on an upper surface of the third passivation layer 295. The photomask may be designed to have various patterns in order to adjust the shape and width of the plurality of conductive capping layers 260.

The conductive capping layer 260 may be made of a conductive material, for example, copper (Cu), aluminum (Al), silver (Ag), tin (Tin), gold (Au), or solder. However, the present disclosure is not limited thereto.

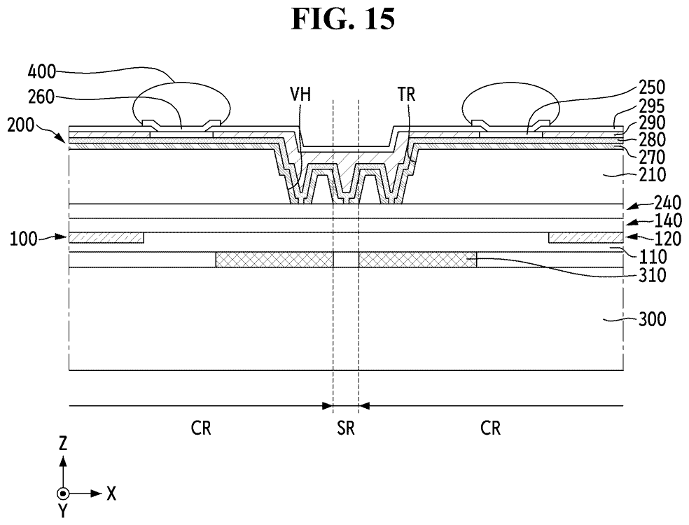

Referring to FIG. 15, a plurality of connection terminals 400 are formed on the conductive capping layer 260. The connection terminal 400 may be made of a conductive material, for example, a low melting point alloy such as Sn—Al—Cu. The image sensor package 1 may be connected to an external circuit via the connection terminal 400.

Accordingly, the connection terminal 400 may be electrically connected to the conductive capping layer 260, the contact pad 250, and the lower electrode layer 280.

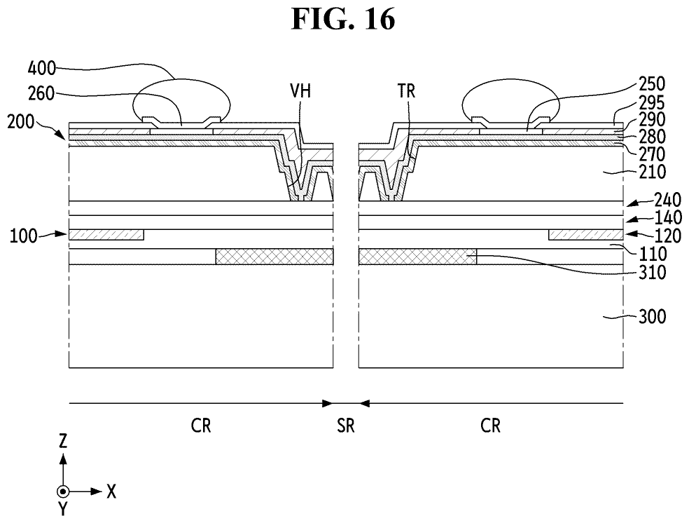

Referring to FIG. 16, a plurality of image sensor packages are formed using a sawing process.

Specifically, a portion of each of the second substrate unit 200, the first substrate unit 100, and the glass plate 300 is removed along the scribe lane area SR to separate the plurality of chip areas CR from each other to form the plurality of image sensor packages 1.

In the method of manufacturing the image sensor package 1 according to the present disclosure, the through-hole VH may be formed by performing an etching process under a high etch selectivity, such that reliability of the manufacturing process may be improved.

In the method of manufacturing the image sensor package 1 according to the present disclosure, an area where the contact pad 250 and the conductive capping layer 260 are connected to the lower electrode layer may be controlled, and thus reliability of the image sensor package 1 may be improved.

The method of manufacturing the image sensor package 1 according to the present disclosure may variously adjust the shapes and widths of the contact pads 250 and the conductive capping layer 260, thereby improving reliability of each image sensor package 1.

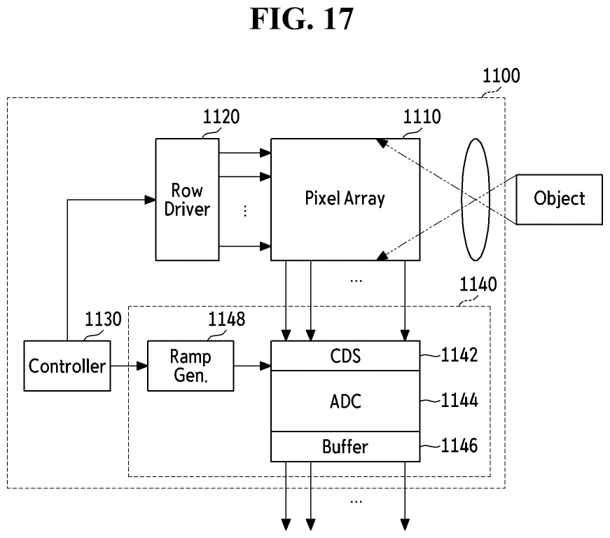

FIG. 17 is a block diagram illustrating a configuration of an image sensor package according to some embodiments of the present disclosure.

Referring to FIG. 17, the image sensor package 1100 may include a pixel array 1110, a controller 1130, a row driver 1120, and a pixel signal processor 1140. The image sensor 1100 includes at least one of the image sensor packages 1 as described with reference to FIGS. 1 to 4.

The pixel array 1110 may include a plurality of unit pixels PX arranged two-dimensionally, and each unit pixel PX may include a photoelectric conversion element PD. The photoelectric conversion element PD may absorb light to generate electric charges, and an electrical signal (output voltage) according to the generated electric charges may be provided to the pixel signal processor 1140 via a vertical signal line VSL.

The unit pixels included in the pixel array 1110 may provide one output voltage at a time on a row basis, and accordingly, the unit pixels belonging to one row of the pixel array 1110 may be simultaneously activated based on a select signal output from the row driver 1120. The unit pixel PX belonging to the selected row may provide the output voltage according to the absorbed light to an output line of a corresponding column.

The controller 1130 may control the row driver 1120 such that the pixel array 1110 absorbs light to accumulate charges, temporarily stores the accumulated charges, and outputs an electrical signal according to the stored charges to the outside out of the pixel array 1110. In addition, the controller 1130 may control the pixel signal processor 1140 to measure the output voltage provided from the pixel array 1110.

The pixel signal processor 1140 may include a correlated double sampler (CDS) 1142, an analog to digital converter (ADC) 1144, and a buffer 1146. The correlated double sampler 1142 may sample and hold the output voltage provided from the pixel array 1110. The correlated double sampler 1142 may doubly sample a specific noise level and a level according to the generated output voltage, and output a level corresponding to a difference therebetween. In addition, the correlated double sampler 1142 may receive a ramp signal generated from a ramp signal generator 1148, compare the ramp signal with the output voltage, and output a comparison result.

The analog-to-digital converter 1144 may convert the analog signal corresponding to the level received from the correlated double sampler 1142 into the digital signal. The buffer 1146 may latch the digital signal, and the latched signal may be sequentially output to the outside out of the image sensor package 1100 and transmitted to an image processor (not shown).

In some embodiments, the pixel array 1110 may be disposed in the first substrate unit 100 included in the image sensor package 1 as described with reference to FIGS. 1 to 16, for example, the sensor 120. In some embodiments, at least some of the row driver 1120, the controller 1130, and the pixel signal processor 1140 may be disposed in the second substrate unit 200 included in the image sensor package 1 as described with reference to FIGS. 1 to 16.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. An image sensor package comprising:
a first substrate including a first surface and a second surface opposite to the first surface and comprising a sensor region including plurality of active pixels;
a second substrate including a first surface and a second surface opposite to the first surface, and comprising a through-hole extending from the first surface of the second substrate to the second surface of the second substrate;
a wiring layer disposed between the first surface of the first substrate and the second surface of the second substrate;
a lower electrode layer comprising a through electrode portion and a rear wiring portion, wherein the through electrode portion is formed in the through-hole and is connected to the wiring layer, and the rear wiring portion covers a portion of the first surface of the second substrate;
a connection terminal disposed on the first surface of the second substrate and electrically connected to the rear wiring portion; and
a pad structure disposed between the rear wiring portion and the connection terminal to electrically connect the rear wiring portion and the connection terminal to each other,
wherein the pad structure comprises:
a contact pad disposed on the rear wiring portion; and
a conductive capping layer disposed between the contact pad and the connection terminal in a vertical direction, and in contact with both the contact pad and the connection terminal.

2. The image sensor package of claim 1, wherein the conductive capping layer comprises:
a base portion parallel to an upper surface of the contact pad;
a peripheral portion spaced apart from the base portion in the vertical direction, and parallel to the upper surface of the contact pad; and
a connection portion connecting the base portion and the peripheral portion to each other.

3. The image sensor package of claim 2, wherein the connection portion forms an acute angle with the upper surface of the contact pad.

4. The image sensor package of claim 2, wherein the peripheral portion has an annular shape surrounding the connection terminal.

5. The image sensor package of claim 2, wherein the base portion and the peripheral portion do not overlap each other in the vertical direction.

6. The image sensor package of claim 1, wherein the wiring layer comprises:
an upper wiring structure disposed on the first surface of the first substrate; and
a lower wiring structure disposed on the second surface of the second substrate and contacting the upper wiring structure.

7. The image sensor package of claim 2, further comprising:
a first passivation layer disposed between the lower electrode layer and the connection terminal in the vertical direction, and positioned at the same vertical level as the contact pad; and
a second passivation layer disposed between the first passivation layer and the conductive capping layer in the vertical direction,
wherein the second passivation layer contacts the contact pad, the peripheral portion of the conductive capping layer, and the connection portion of the conductive capping layer.

8. The image sensor package of claim 1, further comprising:
a glass plate disposed on the second surface of the first substrate; and
a dam structure interposed between the glass plate and the first substrate.

9. An image sensor package comprising:
a first substrate including a first surface and a second surface opposite to the first surface and including a sensor region having a plurality of active pixels;
an upper wiring structure disposed on the first surface;
a second substrate including a first surface and a second surface opposite to the second surface, wherein the second substrate comprises:
a trench extending from the first surface of the second substrate into the second substrate; and
a through-hole extending from a bottom surface of the trench to the second surface of the second substrate;
a lower wiring structure disposed on the second surface of the second substrate and in contact with the upper wiring structure;
a lower electrode layer comprising:
a through electrode portion extending along an inner sidewall and a bottom surface of the through-hole and into the lower wiring structure, wherein the through electrode portion is electrically connected to a portion of the lower wiring structure; and
a rear wiring portion covering a portion of the first surface of the second substrate;
a plurality of connection terminals disposed on the first surface of the second substrate and electrically connected to the rear wiring portion; and
a pad structure disposed between the rear wiring portion and the plurality of connection terminals to electrically connect the rear wiring portion and the plurality of connection terminals,
wherein the pad structure comprises:
a plurality of contact pads disposed on the rear wiring portion; and
a plurality of conductive capping layers respectively disposed on the plurality of contact pads, wherein a portion of each of the plurality of conductive capping layers is spaced apart from each of the plurality of contact pads.

10. The image sensor package of claim 9, wherein each of the plurality of conductive capping layers comprises:
a base portion disposed on an upper surface of the contact pad;
a peripheral portion spaced apart from the upper surface of the contact pad in a vertical direction; and
a connection portion connecting the base portion to the peripheral portion.

11. The image sensor package of claim 10, wherein the base portion, the connection portion, and the peripheral portion are sequentially disposed at different vertical levels.

12. The image sensor package of claim 10, further comprising a passivation layer disposed between the lower electrode layer and the plurality of connection terminals, and the passivation layer having an opening defined therein.

13. The image sensor package of claim 10, further comprising a passivation layer disposed between the lower electrode layer and the plurality of connection terminals,
wherein the base portion is disposed within an opening defined in the passivation layer, and the peripheral portion protrudes outwardly of the passivation layer.

14. The image sensor package of claim 10, wherein the peripheral portion has an annular shape around the connection terminal.

15. The image sensor package of claim 10, wherein the connection portion forms an acute angle with the upper surface of the contact pad.

16. The image sensor package of claim 10, wherein the base portion and the peripheral portion extend parallel to an upper surface of the contact pad.

17. The image sensor package of claim 9, further comprising:
a glass plate disposed on the second surface of the first substrate; and
a dam structure interposed between the glass plate and the first substrate.

18. An image sensor package comprising:
a first substrate having a first surface and a second surface opposite to the first surface and comprising a sensor region including plurality of active pixels;
a glass plate disposed on the second surface of the first substrate;
a dam structure disposed between the glass plate and the first substrate and including an outer side surface vertically aligned with a side surface of the glass plate;
an upper wiring structure disposed on the first surface of the first substrate and including a stacked structure of a plurality of upper wiring patterns and a plurality of upper wiring vias;
a second substrate having a first surface and a second surface opposite to the first surface,
wherein the second substrate comprises:
a trench extending from the first surface of the second substrate into the second substrate; and
a through-hole extending from a bottom surface of the trench to the second surface of the second substrate;
a lower wiring structure disposed on the second surface of the second substrate and in contact with the upper wiring structure, the lower wiring structure comprising a stacked structure of a plurality of lower wiring patterns and a plurality of lower wiring vias;
a first passivation layer covering an inner sidewall of the trench, an inner sidewall of the through-hole, and the first surface of the second substrate;
a lower electrode layer comprising:
a through electrode portion disposed on the first passivation layer and covering the inner sidewall and a bottom surface of the through-hole and extending into the lower wiring structure to be electrically connected to some of the plurality of lower wiring patterns; and
a rear wiring portion electrically connected to the through electrode portion and disposed on a portion of the first passivation layer covering the first surface of the second substrate;
a second passivation layer covering a portion of the lower electrode layer and having a plurality of first openings defined therein to expose the lower electrode layer;
a contact pad disposed in each of the first openings and electrically connected to the lower electrode layer;
a third passivation layer covering the second passivation layer and having a plurality of second openings defined therein to expose a portion of the contact pad;
a conductive capping layer partially disposed in each of the second openings and electrically connected to the contact pad; and
a plurality of connection terminals disposed on the conductive capping layer and electrically connected to the rear wiring portion, the contact pad, and the conductive capping layer.

19. The image sensor package of claim 18, wherein the conductive capping layer comprises:
a base portion disposed in the second opening;
a peripheral portion disposed on the third passivation layer; and
a connection portion connecting the base portion to the peripheral portion.

20. The image sensor package of claim 19,
wherein the second passivation layer is coplanar with the contact pad,
wherein the third passivation layer contacts the contact pad, the peripheral portion of the conductive capping layer, and the connection portion of the conductive capping layer.
